(19) United States
(12) Patent Application Publication
(10) Pub. No.: US 2007/0211833 A1
(43) Pub. Date: Sep. 13, 2007

(54) METHOD AND APPARATUS TO DETECT DATA AND DISK DRIVE USING THE SAME

(75) Inventors: Joo-hyun LEE, Suwon-si (KR); Jae-jin LEE, Suwon-si (KR); Jong-yun YUN, Suwon-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 11/683,635

(22) Filed: Mar. 8, 2007

(30) Foreign Application Priority Data
Mar. 9, 2006 (KR) 2006-22282

(51) Int. Cl. H03D 1/00

(52) U.S. Cl. 375/341

(57) ABSTRACT

A method and an apparatus to detect data in a data storage device, and a method and an apparatus to effectively detect data in channels having characteristics in which bands of data to be reproduced are limited. The method includes partially selecting partial paths from paths of a Viterbi trellis having a number corresponding to an order of a polynomial used in equalization, in an order where path metric values increase from a path having a minimum path metric value, deciding a best path having a minimum path metric value among the partial paths, and detecting data based on the best path.

### CROSS-REFERENCE TO RELATED APPLICATIONS

This application claims priority of Korean Patent Application No. 10-2006-0022282, filed on Mar. 9, 2006, in the Korean Intellectual Property Office, the disclosure of which incorporated herein in its entirety by reference.

### BACKGROUND OF THE INVENTION

1. Field of the Invention

The present general inventive concept relates to a method and an apparatus to detect data in a data storage device, and more particularly, to a method and an apparatus to effectively detect data in channels having characteristics in which a frequency bandwidth of data to be reproduced is limited.

2. Description of the Related Art

In general, a hard disk drive (HDD) is a type of data storage device which contributes to computer system operation by reproducing data written on a disk or by writing data on the disk by using a magnetic head. As hard disk drives (HDD) gradually progress towards high-capacity, high-density and miniaturization, bit per inch (BPI) which is a recording density in a disk rotation direction, and track per inch (TPI) which is a recording density in a diametric direction, increase. Thus, a more delicate mechanism is required.

As recording capacity and density of an HDD increase and asymmetrical channel characteristics increase, bit error rate (BER) characteristics are deteriorated when reproducing data written on the disk. Thus, a more reliable data detection technique is needed.

A partial response maximum likelihood (PRML) technique is generally used to detect data in an HDD. This technique is essentially used when a frequency bandwidth of data to be reproduced is limited, like in channels of the HDD. The PRML apparatus basically includes a partial response (PR) equalizer and a Viterbi detector. In this case, reliable data detection is possible only when the order of PR increases as the linear density of the HDD increases. However, when the order of PR is n, the state number in a trellis of the Viterbi detector is 2ⁿ. Thus, the order of PR cannot be unconditionally increased in consideration of complexity of system implementation. A noise predictive PRML (NPML) technique has been introduced to compensate for the problems of system implementation.

Separately, to compensate for nonlinear characteristics of channels, an adaptive equalization technique is used together with the NPML technique. In the adaptive equalization technique, a PRML (or NPML) detection output is fed back and is used as information to update coefficients of the PR equalizer. However, when a high order of PR is applied, data detection delay in the Viterbi detector corresponding to the PR equalizer increases and effective compensation is not achieved. That is, when the order of PR is n, an instant in which compensation of the PR equalizer starts is (n+1)×(4 or 5). Thus, compensation for an equalizer output generated before the instant is not performed. Accordingly, there is a drawback that nonlinear characteristics of channels are not improved.

### SUMMARY OF THE INVENTION

The present general inventive conept provides a method and an apparatus to detect data in which a number of paths selected in a Viterbi trellis is limited and a best path having a minimum path metric among path metrics before Viterbi detection is completely performed is tentatively decided to update equalizer coefficients. The present general inventive concept also provides disk drive using the method and the apparatus.

Additional aspects and advantages of the present general inventive concept will be set forth in part in the description which follows and, in part, will be obvious from the description, or may be learned by practice of the general inventive concept.

The foregoing and/or other aspects and utilities of the present general inventive concept may be achieved by providing a method of detecting data, the method including partially selecting partial paths from paths of a Viterbi trellis having a number corresponding to an order of a polynomial used in equalization, in an order where path metric values increase from a path having a minimum path metric value, deciding a best path having a minimum path metric value among the partial paths, and detecting data based on the best path.

The foregoing and/or other aspects and utilities of the present general inventive concept may also be achieved by providing a method of detecting data, the method including partially selecting partial paths from paths of a Viterbi trellis having a number corresponding to an order of a polynomial used in equalization, in an order where path metric values increase from a path having a minimum path metric value, tentatively deciding a best path having a minimum path metric value among the selected partial paths, to a window size which is smaller than a Viterbi decoding window size, and updating equalizer coefficients using an error value on which an operation is performed based on the tentatively-decided best path.

The foregoing and/or other aspects and utilities of the present general inventive concept may also be achieved by providing an apparatus to detect data, the apparatus including an equalizer to correct frequency characteristics and timing delay characteristics in consideration of channel characteristics, and a Viterbi detector partially to select partial paths from paths of a Viterbi trellis having a number corresponding to an order of the equalizer, in an order where path metric values increase from a path having a minimum path metric value and to detect data using only the partial paths.

The foregoing and/or other aspects and utilities of the present general inventive concept may also be achieved by providing an apparatus to detect data, the apparatus including an equalizer to correct frequency characteristics and timing delay characteristics of an electrical signal read from a recording medium using a transducer in consideration of channel characteristics, a Viterbi detector to partially select partial paths from paths of a Viterbi trellis having a number corresponding to an order of the equalizer, in an order where path metric values increase from a path having a minimum path metric value, to tentatively decide a best path having a minimum path metric value among the selected partial paths, to a window size which is smaller than a Viterbi decoding window size, and to decide the most similar reference branch value corresponding to the tentatively-decided best path, and a coefficient adjuster to update coefficients of the equalizer using the most similar reference branch value.

The foregoing and/or other aspects and utilities of the present general inventive concept may also be achieved by providing a disk drive including a disk to store information, a transducer to read information from the disk, an amplifier to amplify a signal detected by the transducer, an analog/digital (A/D) transducer to convert the amplified signal into a digital signal, an equalizer to input the digital signal converted by the A/D converter and to correct frequency characteristics and timing delay characteristics in consideration of channel characteristics, and a Viterbi detector to partially select partial paths from paths of a Viterbi trellis having a number corresponding to an order of the equalizer, in an order where path metric values increase from a path having a minimum path metric value and to detect data using only the partial paths.

The foregoing and/or other aspects and utilities of the present general inventive concept may also be achieved by providing a disk drive including a disk to store information, a transducer to read information from the disk, an amplifier to amplify a signal detected by the transducer by varying a gain of the signal to reach a target level, an analog/digital (A/D) transducer to convert the amplified signal into a digital signal, an equalizer to input the digital signal converted by the A/D converter and to correct frequency characteristics and timing delay characteristics in consideration of channel characteristics, and a Viterbi detector to partially select partial paths from paths of a Viterbi trellis having a number corresponding to an order of the equalizer, in an order where path metric values increase from a path having a minimum path metric value, to tentatively to decide a best path having a minimum path metric value among the selected partial paths, to a window size which is smaller than a Viterbi decoding window size, and to decide the most similar reference branch value corresponding to the tentatively-decided best path and a coefficient adjuster to update coefficients of the equalizer using the most similar reference branch value.

The foregoing and/or other aspects and utilities of the present general inventive concept may also be achieved by providing a computer-readable recording medium having recorded thereon a program to perform a method of detecting data including restricting a number of paths to be selected from a trellis of a Viterbi detector, and tentatively deciding a best path having a minimum path metric value among selected partial paths, to a window size which is smaller than a Viterbi decoding window size, so as to update equalizer coefficients, and to perform a method of updating equalizer coefficients.

The foregoing and/or other aspects and utilities of the present general inventive concept may also be achieved by providing a method of detecting data, the method including equalizing data using a partial response polynomial to correct frequency and timing delay characteristics, Viterbi decoding the equalized data with a decoding window of a predetermined size, selecting a number of partial paths from paths of a Viterbi trellis corresponding to an order of the partial response polynomial used in the equalization, selecting a best path from among the partial paths, and detecting data based on the best path.

The foregoing and/or other aspects and utilities of the present general inventive concept may also be achieved by providing a computer readable medium to store a program to execute a method of detecting data, the method including equalizing data using a partial response polynomial to correct frequency and timing delay characteristics, Viterbi decoding the equalized data with a decoding window of a predetermined size, selecting a number of partial paths from paths of a Viterbi trellis corresponding to an order of the partial response polynomial used in the equalization, selecting a best path from among the partial paths, and detecting data based on the best path.

The foregoing and/or other aspects and utilities of the present general inventive concept may also be achieved by providing an apparatus to detect data, the apparatus including an equalizer to correct frequency characteristics and timing delay characteristics of a data signal read from a recording medium, a Viterbi detector to perform Viterbi decoding on the equalized data signal using a predetermined window size, a delay unit to delay the equalized data signal by a window size less than the predetermined window size, and an accumulation unit to output an error value based on the delayed signal and the Viterbi decoded signal.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a plan view illustrating a head disk assembly (HDA) of a disk drive to which the present general inventive concept is applied;

FIG. 2 illustrates a configuration of an electrical circuit of a disk drive in which an apparatus to detect data according to an embodiment of the present general inventive concept is applied;

FIG. 3 illustrates a detailed circuit configuration of a trellis of a Viterbi detector, an equalizer, and a coefficient adjuster according to the present general inventive concept; and

FIG. 4 is a flowchart illustrating a method of detecting data according to an embodiment of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

A hard disk drive is an example of data storage devices to which a method of detecting data according to the present general inventive concept may be applied. The HDD of the present general inventive concept may include a combination of a head disk assembly (HDA) including mechanical parts and an electrical circuit.

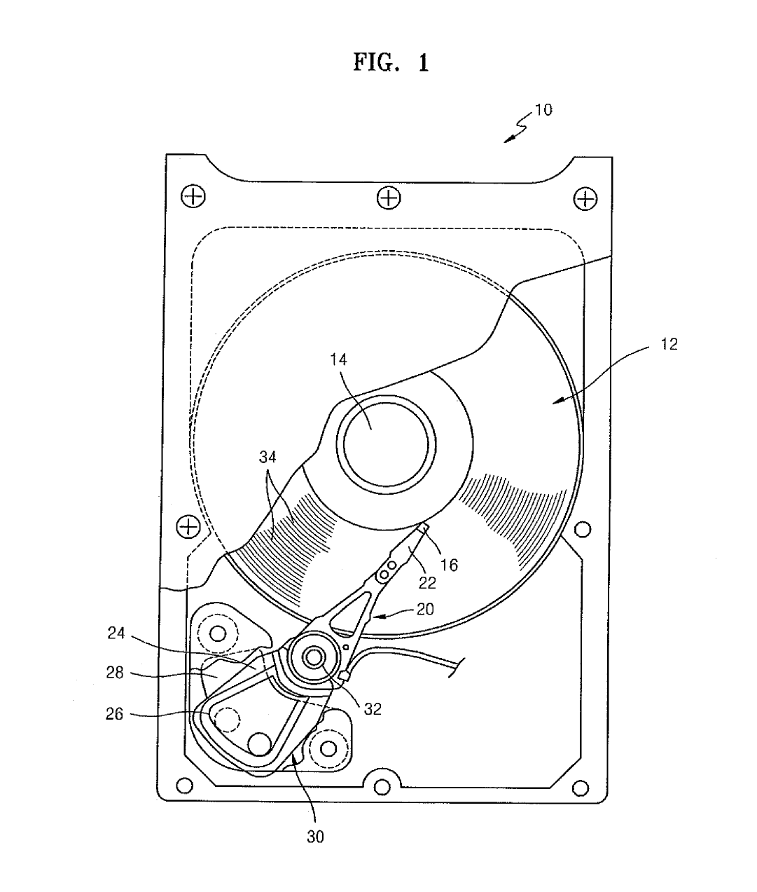

FIG. 1 illustrates a configuration of a head disk assembly (HDA) 10 of a hard disk drive to which the present general inventive concept is applied.

The head disk assembly 10 includes at least one magnetic disk 12 rotated by a spindle motor 14. The disk drive further includes a transducer 16 that is placed to be adjacent to the surface of a disk 12.

The transducer 16 may read or write information from or on the rotating disk 12 by detecting and magnetizing a magnetic field of each disk 12. In general, the transducer 16 faces a surface of each disk 12. Although a single transducer 16 is illustrated, it should be understood that the transducer 16 may include a writing transducer to magnetize the disk 12 and a reading transducer to detect the magnetic field of the disk 12, the writing transducer and the reading transducer being separated from each other. The writing transducer may include magneto-resistive (MR) elements. The transducer 16 is generally referred to as a head.

The transducer 16 may be integrated with a slider 20. The slider 20 is configured to generate an air bearing between the transducer 16 and the surface of the disk 12. The slider 20 is combined with a head gimbal assembly 22. The head gimbal assembly 22 is attached to an actuator arm 24 having a voice coil 26. The voice coil 26 is placed to be adjacent to a magnetic assembly 28 to define a voice coil motor (VCM) 30. A current supplied to the voice coil 26 generates torque used to rotate the actuator arm 24 with respect to a bearing assembly 32. Rotation of the actuator arm 24 may allow the transducer 16 to move across the surface of the disk 12.

Information is generally stored in an annular track of the disk 12. Each track 34 generally includes a plurality of sectors. Each of the sectors includes a data field and an identification field. The identification fieldmay include a gray code to identify sectors and a track (a cylinder). The transducer 16 moves across the surface of the disk 12 so as to read or write information stored in another track.

The disk 12 is largely divided into a user region and a non-user region. The user region is a region in which a user can write or read data substantially, and the non-user region is a region in which information related to a disk drive is stored.

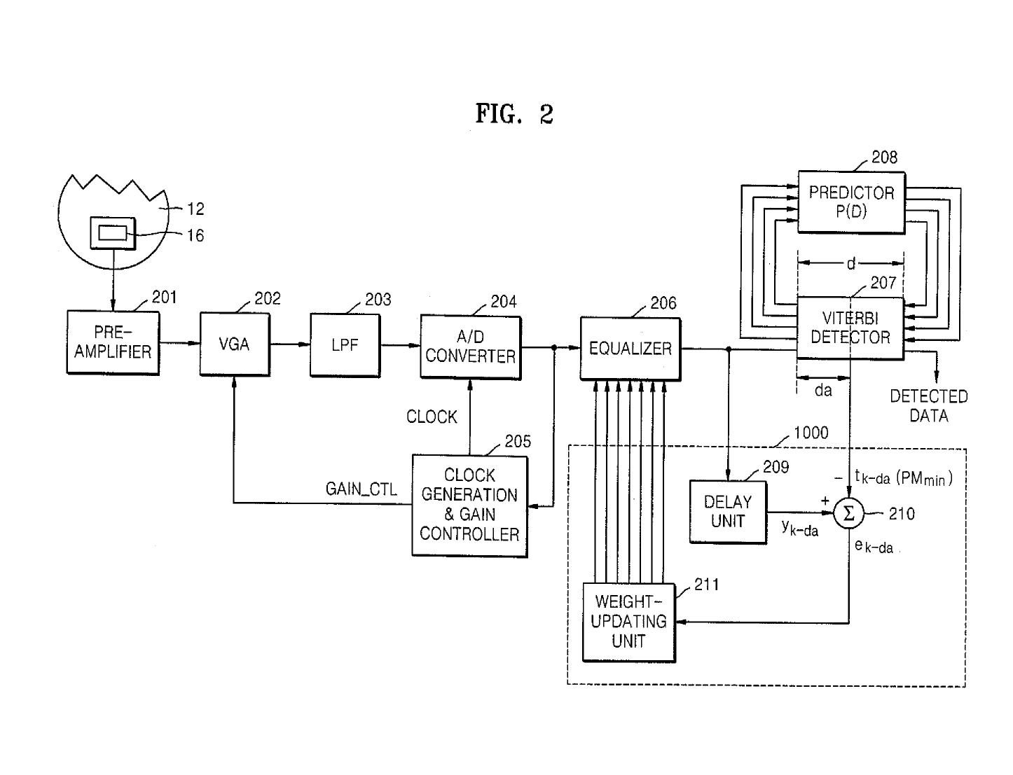

FIG. 2 illustrates a configuration of an electrical system to detect data when data is reproduced in a disk drive according to the present general inventive concept. Referring to FIG. 2, the electrical system to detect data according to the present general inventive concept includes a pre-amplifier 201, a variable gain amplifier (VGA) 202, a low pass filter (LPF) 203, an analog/digital (A/D) converter 204, a clock generation & gain controller 205, an equalizer 206, a Viterbi detector 207, a predictor 208, a delay unit 209, an accumulation operator 210, and a weight-updating unit 211.

The above-described circuit configuration including the delay unit 209, the accumulation operator 210, and the weight-updating unit 211 is a coefficient adjuster 1000.

The pre-amplifier 201 amplifies an electrical signal detected by the transducer 16 from the disk 12 using a fixed gain value.

The VGA 202 amplifies the signal primarily amplified by the pre-amplifier 201 in response to a gain control signal ‘gain_CTL’ to vary a gain value. That is, the clock generation & gain controller 205 monitors an output of the A/D converter 204 and simultaneously, generates a gain control signal ‘gain_CTL’ to decrease a gain when a magnitude of the signal is large and generates a gain control signal ‘gain_CTL’ to increase a gain when a magnitude of the signal is small.

The LPF 203 allows only components of a low frequency band to pass, so as to remove noise components contained in an output signal of the VGA 202.

The A/D converter 204 converts an analog output signal of the LPF 203 into a digital signal rₖ in response to a clock signal generated by the clock generation & gain controller 205.

The digital signal rₖ converted by the A/D converter 204 is output to the equalizer 206.

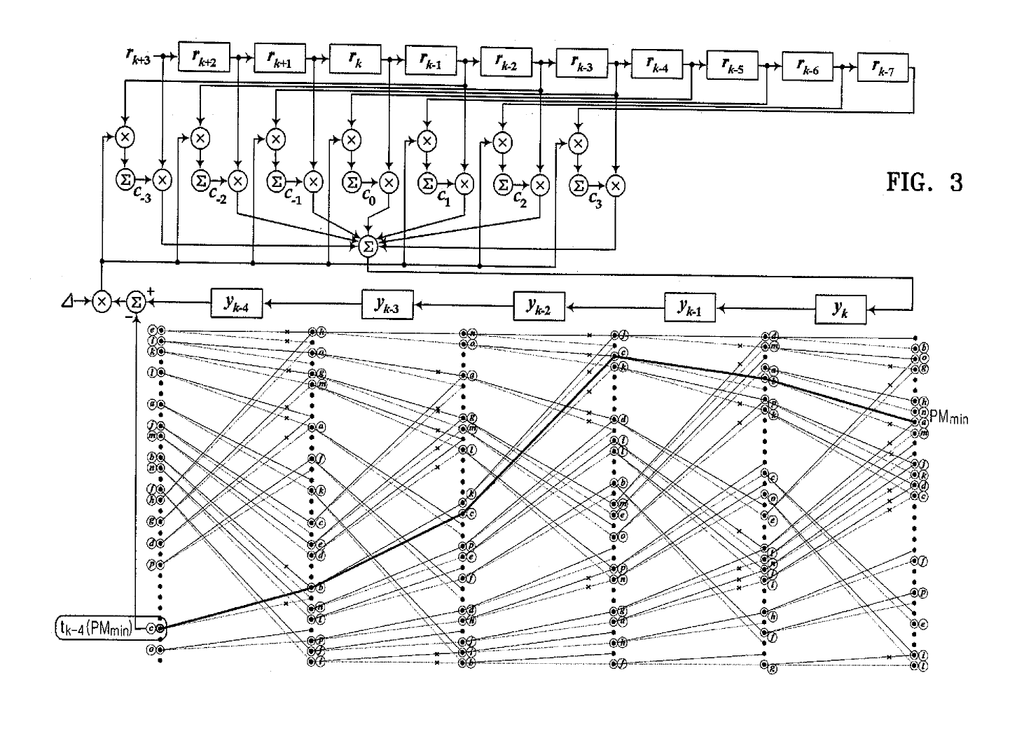

Then, the equalizer 206 includes a delay unit and a finite impulse response (FIR) digital filter and corrects frequency characteristics and timing delay characteristics, so as to be adapted to channel characteristics. As an example, if a fifth-order partial response (PR) polynomial is used in the equalizer 206, the PR polynomial includes seven taps and has coefficients {c₋₃, c₋₂, c₋₁, c₀, c₁, c₂, c₃}, as illustrated in an upper portion of FIG. 3.

If the PR order of the equalizer 206 is 5, a state number of a Viterbi trellis of the Viterbi detector 207 is 2⁵(=32).

As illustrated in a lower portion of FIG. 3, in order to reduce computational complexity in the Viterbi trellis, only partial paths are selected from 32 paths each corresponding to totally 32 states in the order where path metric (PM) values increase from a path having a minimum PM value. In an embodiment of the present general inventive concept, only eight paths a, b, c, d, e, f, g, and h are selected from the 32 paths in the order where PM values increase from a path having a minimum PM value, to be used in data detection.

In addition, when the decoding depth (also referred to as a decoding window size is d in the present general inventive concept, a tentative decision depth (so-called a window size) to adjust equalizer coefficients is ‘da’(<‘d’) and as an example, ‘da’=4.

In this case, an equalizer output signal yₖ for a k-th received signal rₖ is input to the Viterbi detector 207 so as to calculate branch metric and simultaneously is stored in a buffer so as to be used in the tentative decision. An equalizer input value rₖ is also stored in the buffer together with the equalizer output signal yₖ for the k-th received signal rₖ. Accordingly, d buffers are needed in equalizer inputs and outputs so as to update equalizer coefficients. However, since the present general inventive concept is configured so that the tentative decision is made before Viterbi detection is completely performed, ‘da’ buffers in which ‘da’ is smaller than d (in FIG. 3, ‘da’=4) are needed.

Consequently, according to the present general inventive concept, in order to adjust equalizer coefficients in an instant of ‘da’ which is smaller than d, a best path having a minimum path metric PMₘᵢₙ corresponding to y_{k-da} is tentatively decided. In this case, a most similar reference branch value t_{k-da}(PMₘᵢₙ) corresponding to the best path PMₘᵢₙ is decided.

Referring to FIG. 2, the accumulation operator 210 performs an operation on an error value e_{k-da} which is a difference between an output y_{k-da} value of the delay unit 209 to delay an output of the equalizer 206 by ‘da’ and a t_{k-da}(PMₘᵢₙ) value decided by the Viterbi detector 207. That is, e_{k-da}=y_{k-da}−t_{k-da}(PMₘᵢₙ).

Then, the weight-updating unit 211 adjusts coefficients (in FIG. 3, seven coefficients) of the equalizer 206 according to an equalizer coefficient updating algorithm using the error value e_{k-da} on which an operation is performed by the accumulation operator 210, using a block configuration illustrated in the upper portion of FIG. 3. As an example, the equalizer coefficient updating algorithms may include a least mean square (LMS) equalizer coefficient updating algorithm.

The predictor 208 predicts noises using a noise prediction algorithm and predicted noise information is used to prevent incorrect data detection caused by noises when detecting data of the Viterbi detector 207.

The above-described equalizer coefficient updating process is repeatedly performed on each symbol.

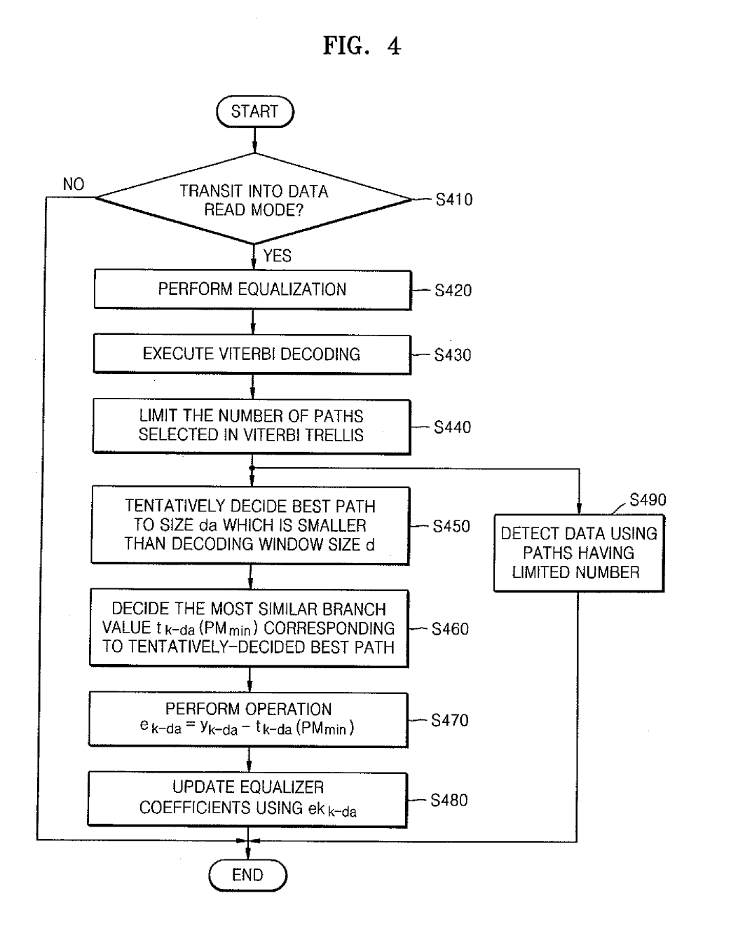

A method of detecting data according to the present general inventive concept will now be described with reference to the flowchart of FIG. 4.

In operation S410, it is determined whether or not an apparatus to reproduce data is transited from a current mode into a data read mode.

As a result of the determination in operation S410, if the apparatus is transited to the data read mode, a signal read from a recording medium is equalized using a partial response (PR) polynomial as an example in operation S420. Equalization is a process to correct frequency characteristics and timing delay characteristics, so as to adapt channel characteristics.

In operation S430, Viterbi decoding is executed using an equalized signal with a decoding window size d.

A number of paths selected in a Viterbi trellis during Viterbi decoding is limited in operation S440. That is, in order to reduce computational complexity in the Viterbi trellis, as illustrated in the lower portion of FIG. 3, only partial paths are selected from 32 paths each corresponding to 32 states in an order where path metric (PM) values increase from a path having a minimum PM value. In an embodiment of the present general inventive concept, only eight paths a, b, c, d, e, f, g, and h are selected from the 32 paths in the order where PM values increase from a path having a minimum PM value, to be used in data detection.

In operation S450, a best path is tentatively decided to the size ‘da’ which is smaller than the decoding window size d. The size ‘da’ is a tentative decision depth which adjusts equalizer coefficients. Accordingly, in order to correct equalizer coefficients in the instant of ‘da’, a best path having a minimum path metric PMₘᵢₙ corresponding to y_{k-da} is tentatively decided.

In operation S460, a most similar reference branch value t_{k-da}(PMₘᵢₙ) corresponding to the tentatively-decided best path PMₘᵢₙ is decided.

In operation S470, an operation on an error value e_{k-da} which is a difference between an output y_{k-da} value obtained by delaying an output of the equalizer by da and a t_{k-da}(PMₘᵢₙ) value decided in operation S460 by the Viterbi detector 207, is performed.

In operation S480, coefficients of the equalizer are updated according to an equalizer coefficient updating algorithm using the error value e_{k-da} on which an operation is performed in operation S470. As an example, the equalizer coefficient updating algorithms may include a least mean square (LMS) equalizer coefficient updating algorithm.

In operation S490, a best path is decided using the limited number of paths selected in operation S440 and data is detected in a unit of the decoding window size d based on the best path.

Through the above-described method, disadvantages that the structure of a trellis of the Viterbi detector is complicated by an increase in equalization order and a simultaneous increase in the amount of computation can be improved. In addition, the period when equalizer coefficients are updated is reduced to effectively compensate for nonlinear characteristics.

As described above, according to the present general inventive concept, the number of paths selected in the trellis of the Viterbi detector is limited and the best path is tentatively decided to a size which is smaller than the decoding window size to update equalizer coefficients. Accordingly, the present general inventive concept has the disadvantages that the structure of the trellis of the Viterbi detector is complicated by an increase in equalization order and a simultaneous increase in the amount of computation required. In addition, by reducing the period when equalizer coefficients are updated, the present general inventive concept effectively compensates for the effects of nonlinear characteristics.

In the present general inventive concept, for convenience of explanation, a hard disk drive (HDD) has been described. However, the present general inventive concept can be applied to a variety of different kinds of data storage devices including an optical disk drive having limited channel characteristics, and the present general inventive concept is not limited thereto.

The present general inventive concept can also be embodied as a method, an apparatus, or a system. When the present general inventive concept is embodied using software, elements of the present general inventive concept may be code segments that carry out essential works. Programs or code segments can be stored in a computer-readable medium or transmitted by a computer data signal combined with carrier waves via a transmission medium or communication network. The computer-readable medium can be any data storage device that can store or transmit data which can be thereafter read by a computer system. Examples of the computer-readable medium include electronic circuits, semiconductor memory devices, read-only memory (ROM), flash memory, erasable ROM, floppy disks, optical disks, hard disks, optical fiber medium, radio frequency (RF) network, and the like. The computer data signal can be any signal that can be transmitted onto an electronic network channel, optical fiber, air, an electronic field, a RF network, and the like. The method illustrated in FIG. 4 may be stored in the computer-readable medium in a form of computer-readable codes to perform the method when the computer reads the computer-readable codes of the computer-readable medium.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A method of detecting data, the method comprising:
partially selecting partial paths from paths of a Viterbi trellis having a number corresponding to an order of a polynomial used in equalization, in an order where path metric values increase from a path having a minimum path metric value;
deciding a best path having a minimum path metric value among the partial paths; and
detecting data based on the best path.

2. The method of claim 1, further comprising:
deciding the most similar reference branch value corresponding to the best path; and
updating coefficients of an equalizer using a difference between the most similar reference branch value and a value obtained by delaying an output of the equalizer.

3. A computer-readable recording medium having recorded thereon a program to perform the method of any one of claims 1 and 2.

4. A method of detecting data, the method comprising:
partially selecting partial paths from paths of a Viterbi trellis having a number corresponding to an order of a polynomial used in equalization, in an order where path metric values increase from a path having a minimum path metric value;
tentatively deciding a best path having a minimum path metric value among the selected partial paths, to a window size which is smaller than a Viterbi decoding window size; and
updating equalizer coefficients using an error value on which an operation is performed based on the tentatively-decided best path.

5. The method of claim 4, wherein the updating of the equalizer coefficients comprises:
deciding the most similar reference branch value corresponding to the tentatively-decided best path;
performing an operation on an error value which is a difference between an equalizer output value obtained by delaying the best path by a tentatively-deciding window size and the reference branch value; and
updating coefficients of an equalizer using the error value.

6. The method of claim 4 or 5, wherein the updating of the coefficients of the equalizer comprises updating coefficients of an equalizer using a least mean square (LMS) algorithm.

7. A computer-readable recording medium having recorded thereon a program to perform the method of any one of claims 4 through 6.

8. An apparatus to detect data, the apparatus comprising:
an equalizer to correct frequency characteristics and timing delay characteristics in consideration of channel characteristics; and
a Viterbi detector to partially select partial paths from paths of a Viterbi trellis having a number corresponding to an order of the equalizer, in an order where path metric values increase from a path having a minimum path metric value and to detect data using only the partial paths.

9. An apparatus to detect data, the apparatus comprising:
an equalizer to correct frequency characteristics and timing delay characteristics of an electrical signal read from a recording medium using a transducer in consideration of channel characteristics;
a Viterbi detector to select partial paths from paths of a Viterbi trellis having a number corresponding to an order of the equalizer, in an order where path metric values increase from a path having a minimum path metric value, to tentatively decide a best path having a minimum path metric value among the selected partial paths, to a window size which is smaller than a Viterbi decoding window size, and to decide the most similar reference branch value corresponding to the tentatively-decided best path; and
a coefficient adjuster to update coefficients of the equalizer using the most similar reference branch value.

10. The apparatus of claim 9, wherein the coefficient adjuster comprises:
a unit to delay the best path by a tentatively-deciding window size;
a unit to perform an error value which is a difference between an equalizer output value delayed by the window size and the most similar reference branch value; and
a unit for to update coefficients of an equalizer using the error value.

11. A disk drive comprising:
a disk to store information;
a transducer to read information from the disk;
an amplifier to amplify a signal detected by the transducer;
an analog/digital (A/D) transducer to convert the amplified signal into a digital signal;
an equalizer to input the digital signal converted by the A/D converter and to correct frequency characteristics and timing delay characteristics in consideration of channel characteristics; and
a Viterbi detector to partially select partial paths from paths of a Viterbi trellis having a number corresponding to an order of the equalizer, in an order where path metric values increase from a path having a minimum path metric value and to detect data using only the partial paths.

12. A disk drive comprising:
a disk to store information;
a transducer to read information from the disk;
an amplifier to amplify a signal detected by the transducer by varying a gain of the signal to reach a target level;
an analog/digital (A/D) transducer to convert the amplified signal into a digital signal;
an equalizer to input the digital signal converted by the A/D converter and to correct frequency characteristics and timing delay characteristics in consideration of channel characteristics; and
a Viterbi detector to partially select partial paths from paths of a Viterbi trellis having a number corresponding to an order of the equalizer, in an order where path metric values increase from a path having a minimum path metric value, to tentatively decide a best path having a minimum path metric value among the selected partial paths, to a window size which is smaller than a Viterbi decoding window size, and to decide the most similar reference branch value corresponding to the tentatively-decided best path; and
a coefficient adjuster to update coefficients of the equalizer using the most similar reference branch value.

13. The disk drive of claim 12, wherein the coefficient adjuster comprises:
a unit to delay the best path by a tentatively-deciding window size;
a unit to perform an error value which is a difference between an equalizer output value delayed by the window size and the reference most similar branch value; and
a unit to update coefficients of an equalizer using the error value.

14. A method of detecting data, the method comprising:
equalizing data using a partial response polynomial to correct frequency and timing delay characteristics;
Viterbi decoding the equalized data with a decoding window of a predetermined size;
selecting a number of partial paths from paths of a Viterbi trellis corresponding to an order of the partial response polynomial used in the equalization;
selecting a best path from among the partial paths; and
detecting data based on the best path.

15. The method of claim 14, wherein the number of partial paths are selected in a predetermined order based on path metric values of the paths.

16. The method of claim 15, further comprising:
tentatively deciding the best path having a minimum path metric value among the selected partial paths, with a window size which is smaller than the predetermined Viterbi decoding window size;
performing an operation based on the tentatively-decided best path; and
updating equalizer coefficients using an error value based on the performed operation.

17. The method of claim 14, wherein the data detection is performed based on a partial response maximum likelihood.

18. The method of claim 14, wherein the data detection is performed based on a noise predictive partial response maximum likelihood.

19. A computer readable medium to store a program to execute a method of detecting data, the method comprising:
equalizing data using a partial response polynomial to correct frequency and timing delay characteristics;
Viterbi decoding the equalized data with a decoding window of a predetermined size;
selecting a number of partial paths from paths of a Viterbi trellis corresponding to an order of the partial response polynomial used in the equalization;
selecting a best path from among the partial paths; and
detecting data based on the best path.

20. An apparatus to detect data, the apparatus comprising:
an equalizer to correct frequency characteristics and timing delay characteristics of a data signal read from a recording medium;
a Viterbi detector to perform Viterbi decoding on the equalized data signal using a predetermined window size;
a delay unit to delay the equalized data signal by a window size less than the predetermined window size; and
an accumulation unit to output an error value based on the delayed signal and the Viterbi decoded signal.
